(19) United States
(12) Patent Application Publication
(10) Pub. No.: US 2026/0074691 A1
(43) Pub. Date: Mar. 12, 2026

(54) GaN Gate Driver for EMI Optimization During Turn-on and Turn-off

(71) Applicant: Renesas Design (UK) Limited, Bourne End (GB)

(72) Inventors: Rakshitha Salian, San Jose, CA (US); Vijay Kanagala, Campbell, CA (US); Kai-wen Chin, Campbell, CA (US)

(21) Appl. No.: 18/827,565

(22) Filed: Sep. 6, 2024

(51) Int. Cl. H03K 17/16; G01R 31/52; H02M 1/08

(52) U.S. Cl. CPC H03K 17/165; H02M 1/08; G01R 31/52

(57) ABSTRACT

An integrated circuit is provided for driving the gate of a GaN power switch transistor in a switching power converter. During a first portion of an on-time period for the GaN power switch transistor, the integrated circuit charges the gate through a relatively high pull-up resistance. During a second portion of the on-time period, the integrated circuit charges the gate through a relatively low pull-up resistance. During a first portion of an off-time period for the GaN power switch transistor, the integrated circuit discharges the gate through a relatively low pull-down resistance and then discharges the gate through a relatively high pull-down resistance in response a voltage of the gate falling below a threshold voltage.

### TECHNICAL FIELD

This application relates to switching power converters, and more particularly to a to a gate driver for a GaN power switch transistor with EMI optimization during both turn-on and turn-off.

### BACKGROUND

The use of gallium nitride (GaN) transistors has revolutionized power electronic systems. As compared to a traditional metal-oxide-semiconductor field-effect transistor (MOSFET), a comparable GaN transistor has improved efficiency, higher power density, and faster switching capabilities. But the faster switching speed of GaN devices comes at the cost of increased electromagnetic interference (EMI) noise. The rapid voltage transition from the increased switching speed may produce disruptive EMI noise. For example, in a flyback converter the power switch transistor may comprise an n-type GaN transistor having a drain connected to a primary winding and a source coupled to ground. Prior to the power switch transistor being switched on, the drain is charged to (or above) the input voltage to the primary winding. The input voltage is rectified from the AC mains and can thus be more than 100 V depending upon the AC mains cycling. With the power switch transistor being fully switched on, the drain is grounded. The drain of the power switch transistor is thus subjected to a relatively high rate of voltage change (dV/dt) during the power switch transistor turn on. An analogous voltage change occurs during the power switch transistor turn off. The rapid changes in the drain voltage of the power switch transistor while switching on and off may lead to an undesirable level of electromagnetic interference (EMI).

To reduce the EMI from the power switch cycling, it is conventional to drive the power switch transistor on through a relatively complicated drive circuit that includes a high-voltage Miller capacitor, a bipolar junction transistor, a diode, and external resistors. These drive circuit components increase cost and occupy circuit board space.

### SUMMARY

In accordance with an aspect of the disclosure, an integrated circuit for a switching power converter is provided that includes: a gate drive circuit configured to charge a gate of a GaN power switch transistor through a variable pull-up resistance including a first pull-up resistance and a second pull-up resistance and to discharge the gate of the GaN power switch transistor through a variable pull-down resistance including a first pull-down resistance and a second pull-down resistance, wherein the first pull-up resistance is greater than the second pull-up resistance, and wherein the second pull-down resistance is greater than the first pull-down resistance; and a gate drive control circuit configured to command the gate drive circuit to charge the gate through the first pull-up resistance during an initial first portion of an on-time period for the GaN power switch transistor and to charge the gate through the second pull-up resistance during a second portion of the on-time period, wherein the gate drive control circuit is further configured to command the gate drive circuit to discharge the gate through the first pull-down resistance during an initial first portion of an off-time period for the GaN power switch transistor and to discharge the gate through a second pull-down resistance during a second portion of the off-time period.

In accordance with another aspect of the disclosure, a method of driving a gate of a GaN power switch transistor in a switching power converter is provided that includes: charging the gate through a first pull-up resistance during an initial portion of an on-time period for the GaN power switch transistor while a gate voltage of the GaN power switch transistor is less than a first threshold voltage; charging the gate through a second pull-up resistance that is less than the first pull-up resistance during a second portion of the on-time period while the gate voltage is greater than the first threshold voltage; discharging the gate through a first pull-down resistance during an initial portion of an off-time period for the GaN power switch transistor while the gate voltage is greater than a first threshold voltage; and discharging the gate through a second pull-down resistance during a second portion of the off-time period in response to the gate voltage falling below the first threshold voltage, wherein the second pull-down resistance is greater than the first pull-down resistance.

In accordance with yet another aspect of the disclosure, a switching power converter is provided that includes: an inductor; a GaN power switch transistor connected to the inductor; and an integrated circuit configured to: charge a gate of the GaN power switch transistor through a first pull-up resistance during an initial first portion of an on-time period for the GaN power switch transistor, charge the gate through a second pull-up resistance during a second portion of the on-time period, discharge the gate through a first pull-down resistance during an initial first portion of an off-time period for the GaN power switch transistor, and discharge the gate through a second pull-down resistance during a second portion of the off-time period.

These and other aspects of the invention will become more fully understood upon a review of the detailed description, which follows. Other aspects, features, and embodiments will become apparent to those of ordinary skill in the art, upon reviewing the following description of specific, exemplary embodiments in conjunction with the accompanying figures. While features may be discussed relative to certain embodiments and figures below, all embodiments can include one or more of the advantageous features discussed herein. In other words, while one or more embodiments may be discussed as having certain advantageous features, one or more of such features may also be used in accordance with the various embodiments discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 illustrates a flyback converter with an integrated circuit for driving a gate of a GaN power switch transistor in accordance with an aspect of the disclosure.

FIG. 2 is a more detailed view of the integrated circuit of FIG. 1 in accordance with an aspect of the disclosure.

FIG. 3 illustrates some operating waveforms for the integrated circuit of FIG. 2 in accordance with an aspect of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

To avoid the complications of using a Miller capacitor approach, adaptive gate drivers have been developed for driving the gate voltage of silicon-based switching power converters. In such adaptive gate drivers, the output impedance of the gate driver is modified depending upon the gate voltage to reduce the electromagnetic interference (EMI) noise during the turn-on times of the power switch transistors. As the gate voltage passes various threshold voltages, the output impedance is varied accordingly. Some or all of the threshold voltages are based on the Miller plateau level of the gate voltage. As known in the MOSFET arts, a Miller plateau period occurs after the gate-to-source voltage for the power switch transistor has reached the transistor threshold voltage. The drain voltage then begins to fall due to the channel conduction, which tends to pull the gate voltage lower due to a gate-to-drain parasitic capacitance of the power switch transistor M1. The gate-to-drain parasitic capacitance is highly non-linear such that it is relatively small as the drain voltage begins to fall and increases in magnitude as the drain voltage approaches ground. The net result is that the gate voltage is relatively constant during the Miller plateau period, which ends once the gate-to-drain capacitance is discharged.

This dependence on the Miller plateau voltage complicates the porting of a traditional adaptive gate driver for a silicon-based power switch transistor to drive the gate voltage of a GaN power switch transistor. As compared to silicon-based power switch transistors, gallium-nitride (GaN) power switch transistors offer improved efficiency, increased power density, and faster switching capabilities. As a result, GaN power switch transistors are a popular choice for AC-DC switching power converters such as flyback converters. But the Miller plateau voltage is relatively indistinct for GaN devices. A traditional adaptive gate driver will thus have challenges in accurately setting its threshold voltages due to the vagueness of the Miller plateau voltage for GaN devices. An improved gate driver is provided herein for the cycling of GaN power switch transistors that does not depend upon detecting the Miller plateau voltage.

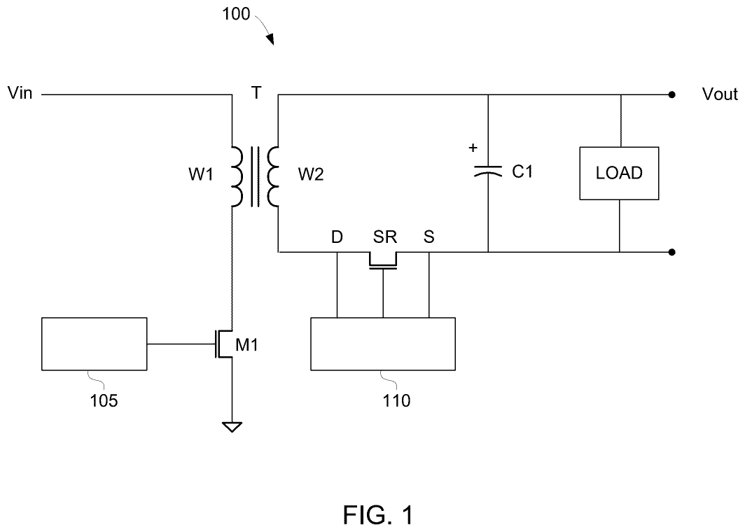

The following discussion will be directed to a gate driver for flyback converter implementations that use GaN power switch transistors, but it will be appreciated that the improved gate driver disclosed herein may be advantageously employed for the driving of any suitable GaN power switch transistor such as in a buck or a boost converter. An example flyback converter 100 is shown in FIG. 1 that includes an improved gate driver in an integrated circuit 105. Flyback converter 100 includes a transformer T having a primary winding W1 and a secondary winding W2. During operation, adaptive gate driver 105 charges the gate of an n-type GaN power switch transistor M1 connected to the primary winding W1 to switch on the power switch transistor M1 for an on-time period. The primary winding W1 also connects to an input voltage rail carrying a rectified input voltage (Vin). When the power switch transistor M1 is cycled on, a primary winding current begins to flow through the primary winding W1 and the power switch transistor M1 into ground. Once a desired peak winding current has been reached, a primary-side controller (not illustrated) may then control the gate driver 105 to cycle off the power switch transistor M1. As used herein, “connected” refers to a direct electrical connection such as through a conducting lead whereas “coupled” refers to an electrical connection in which the connection may be through an intervening element such as a resistor or a diode.

A secondary-side controller U2 controls a synchronous rectifier (SR) switch transistor that couples between a return output terminal and the secondary winding W2. This SR control is in response to monitoring a drain (D) to source(S) voltage (VDS) across the SR switch transistor. Based upon the drain-to-source voltage VDS, the secondary-side controller 110 detects whether the power switch transistor M1 has cycled off so that the SR switch transistor may be switched on to allow the secondary winding current to flow and charge an output voltage Vout that is supported by an output capacitor C1.

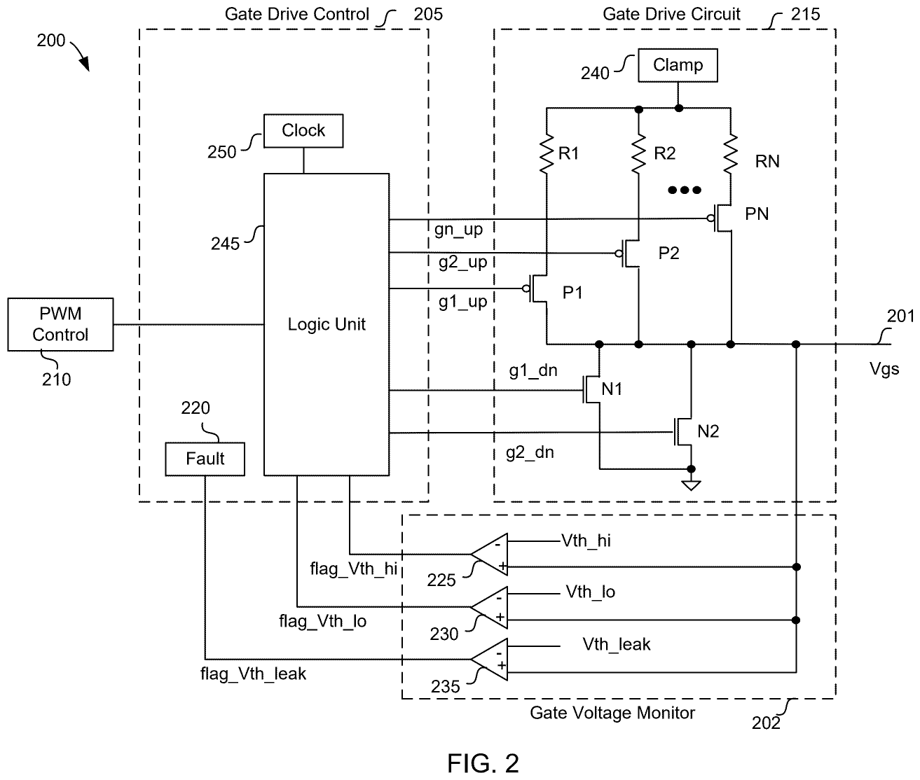

An example gate driver 200 is shown in more detail in FIG. 2. For illustration clarity and brevity, the corresponding flyback converter is represented by just a node 201 for the gate voltage Vgs. A modulation control circuit 220 provides a modulation control signal to a gate drive control circuit 205. For example, the modulation control circuit 220 may be a pulse-width modulation (PWM) control circuit that produces a (PWM control signal to control the desired on-time period for the power switch transistor. The modulation control circuit 210 may be part of a primary-side controller or part of a secondary-side controller. If the modulation control circuit 210 is located on the secondary-side of the transformer, the PWM control signal would be transmitted across a ground-isolating channel such as an opto-isolator. Regardless of where the modulation control circuit 210 is located, it generates the PWM control signal responsive to feedback on the various operating signals such as the output voltage Vout or the input voltage Vin.

The adaptive gate driver 200 includes a gate drive circuit 215 that implements a variable gate drive resistance and includes a gate voltage monitor or sensing circuit 202 that monitors the gate voltage (which is equivalent to the gate-to-source voltage Vgs of the power switch transistor since its source is grounded). The gate voltage sensing circuit 202 includes a comparator 225, a comparator 230, and a comparator 235 for comparing the gate voltage of the power switch transistor to respective threshold voltages. In particular, the comparator 230 uses a relatively low threshold voltage Vth_lo to assert a comparator output signal flag_Vth_lo when the gate voltage has risen to equal Vth_lo. During the switch turn off, the comparator output signal flag_Vth_low is de-asserted to indicate that the gate voltage has fallen below Vth_lo. Similarly, the comparator 225 uses a relatively larger reference voltage Vth_hi to assert a comparator output signal flag_Vth_hi when the gate voltage has risen to equal the high threshold voltage Vth_hi during the switch turn on period. During the switch turn off period, the comparator output signal flag_Vth_hi is de-asserted to indicate that the gate voltage has fallen below Vth_hi. There are thus three periods during the power switch transistor turn-on period and during the power switch turn-off period. A first period T1 extends from the start of the turn-on time delay until the gate voltage has risen to equal Vth_lo. A second period T2 extends from the end of period T1 until the gate voltage has risen to equal Vth_hi (Vth_hi being greater than Vth_lo). A final turn-on period T3 extends from when the gate voltage has risen above Vth_hi until the end of the on-time period.

The turn-off period following the turn-on period is analogous in that it includes a period T4 that extends from the end of the turn-on period to when the gate voltage falls below Vth_hi. At the end of period T4, the period T5 then extends from the end of the period T4 to when a timed delay has ended. Finally, a period T6 extends from the end of the period T5 to when the gate voltage has discharged to ground.

The gate drive circuit 215 drives the gate voltage with a pull-up gate drive resistance during the switch turn-on period that varies depending upon which of the periods T1, T2, and T3 is active. Similarly, the gate drive circuit discharges the gate voltage with a pull-down gate drive resistance that varies depending upon which of the periods T4, T5, and T6 is active. During periods T1 and T2 of the switch turn-on period, the gate drive circuit 215 charges the gate through a high pull-up resistance. But during period T3, the gate drive circuit 215 charges the gate through a relatively low pull-up resistance that is less than the relatively high pull-up resistance used during period T1. In period T4, the gate drive circuit 215 discharges the gate voltage through a relatively low pull-down resistance to reduce the turn-off delay. Then, the pull-down resistance is switched to a relatively high pull-down resistance during period T5. Finally, the gate drive circuit 215 again discharges the gate voltage through a relatively low pull-down resistance during period T6. But note that it may be undesirable to increase the gate drive resistance during a critical conduction mode of operation in which a relatively large amount of power must be delivered to the load. The pull-up gate drive resistance during period T1 and period T2 and the pull-down gate drive resistance during period T5 may thus be the same or even lower than the values used in the discontinuous conduction mode of operation.

To implement the various pull-up resistances, the gate drive circuit 215 includes a plurality of n PMOS pull-up transistors ranging from a first PMOS pull-up transistor P1 to an nth PMOS pull-up transistor Pn, n being a positive plural integer. Each pull-up transistor has its source coupled through a corresponding resistor to a power supply voltage rail such as supplied by a voltage clamp 240 through a corresponding resistance and a drain connected to the gate of the power switch transistor M1. For example, transistor P1 has its source coupled to the voltage clamp 240 through a resistor R1 and its drain connected to the gate of the power switch transistor M1, transistor P2 has its source coupled to the voltage clamp 240 through a resistor R2 and its drain connected to the gate of the power switch transistor M1, and so on such that the nth transistor Pn has its source coupled to the voltage clamp 240 through a resistor Rn and its drain connected to the gate of the power switch transistor M1. In some embodiments, the resistors may be conceptual in that they would be provided by the on-resistance of the respective transistor. Alternatively, the resistors may be external to the transistors. In addition, the resistors may instead couple between the corresponding transistor's drain and the gate of the power switch transistor M1 in alternative implementations.

To produce a low pull-up resistance, the drive control circuit 305 may switch on each (or most) of the pull-up transistors P1 through Pn. The gate drive pull-up resistance increases as fewer and fewer of the transistors P1 through Pn are switched on. To control the gate drive pull-up resistance depending upon whether period T1, T2, or T3 is active, gate drive control circuit 205 may include a logic circuit 245. Logic circuit 245 may comprise a state machine, a microcontroller, or a microprocessor. During cycling of the power switch transistor M1, logic circuit 245 responds to the PWM control signal to then switch on the power switch transistor M1 for the desired on-time period. For a large pulse width, the on-time period is relatively long whereas it is shorter for smaller pulse widths. The beginning of the on-time period may be coordinated by a clock signal from a clock 250. Logic circuit 245 controls which of the pull-up transistors P1 through Pn is switched on through a corresponding gate drive signal. For example, the logic circuit 245 grounds a gate drive signal g1_up to switch on the pull-up transistor P1, grounds a gate drive signal g2_up to switch on the pull-up transistor P2, and so on such that the logic circuit 245 grounds a gate drive signal gn_up to switch on the pull-up transistor Pn. Should one of the gate drive signals g1_up through gn_up be charged to a power supply voltage, the corresponding pull-up transistor is off. In alternative embodiments, current sources may be used to control the gate drive resistance level during the on-time period for the power switch transistor M1.

The pull-down resistance is implemented similarly such as through a plurality of NMOS pull-down transistors each having a source coupled to ground and a drain coupled to the gate of the power switch transistor M1. In the gate drive circuit 215, there are two pull-down transistors ranging from a first pull-down transistor N1 to a second pull-down transistor N2, but it will be appreciated that more than two pull-down transistors may be used in alternative implementations. In the gate driver 200, the on-resistance of the pull-down transistors N1 and N2 controls the gate drive pull-down resistance but it will be appreciated that the pull-down transistors may be arranged in series with a corresponding resistor analogously as shown for the pull-up transistors. To produce a low gate drive pull-down resistance, the drive control circuit 205 may switch on each of the pull-down transistors N1 and N2. The gate drive pull-down resistance increases if just one of the transistors N1 and N2 is switched on. To control whether the pull-down transistor M1 is on, the logic circuit 245 asserts a gate drive signal g1_dn to the power supply voltage. Conversely, the logic circuit 245 grounds the gate drive signal g1_dn to switch off the pull-down transistor M1. Similarly, the logic circuit 245 asserts a gate drive signal g2_dn to the power supply voltage to switch on the pull-down transistor M2. Conversely, the logic circuit 245 grounds the gate drive signal g2_dn to switch off the pull-down transistor M2.

During period T4, the logic circuit 245 switches on both the pull-down transistors M1 and M2 to produce the desired low pull-down impedance. In period T5, the logic circuit 245 switches on just one of the pull-down transistors M1 and M2 to increase the pull-down impedance. Finally, in period T6, the logic circuit 245 again switches on both of the pull-down transistors to produce the desired low pull-down impedance to finish the turn-off period of the power switch transistor M1.

With respect to the timing of the periods T1 through T6, the threshold voltages used by the gate voltage monitor 240 are fixed values. This lack of adaptation of the threshold voltages with respect to the Miller plateau gate voltage of the power switch transistor M1 is quite advantageous due to the indistinct nature of the Miller plateau voltage for GaN devices. The low threshold voltage Vth_lo is set such that it is assured that the threshold voltage of the power switch transistor M1 has been reached once the comparator 230 asserts the flag_Vth_lo signal to signal to the logic circuit 245 that the gate voltage has risen above the low threshold voltage Vth_lo. The duration of the period T1 from the start of the turn-on period to the assertion of the flag_Vth_lo thus constitutes the main turn-on delay for the power switch transistor M1. In both period T1 and T2, the gate drive circuit 215 implements a relatively high pull-up gate impedance that is denoted herein as Rg1. With respect to setting Rg1, the logic unit 245 may time the duration of the period T1 to determine whether the main turn-on delay is meets design requirements. Should the period T1 be too short, the corresponding rate of change for the drain voltage of the power switch transistor M1 may produce excessive EMI noise. Conversely, if the period T1 is too long, the switching speed of the power switch transistor M1 may be too slow to sufficiently regulate an output voltage of the corresponding switching power converter and contributes to higher switching loss.

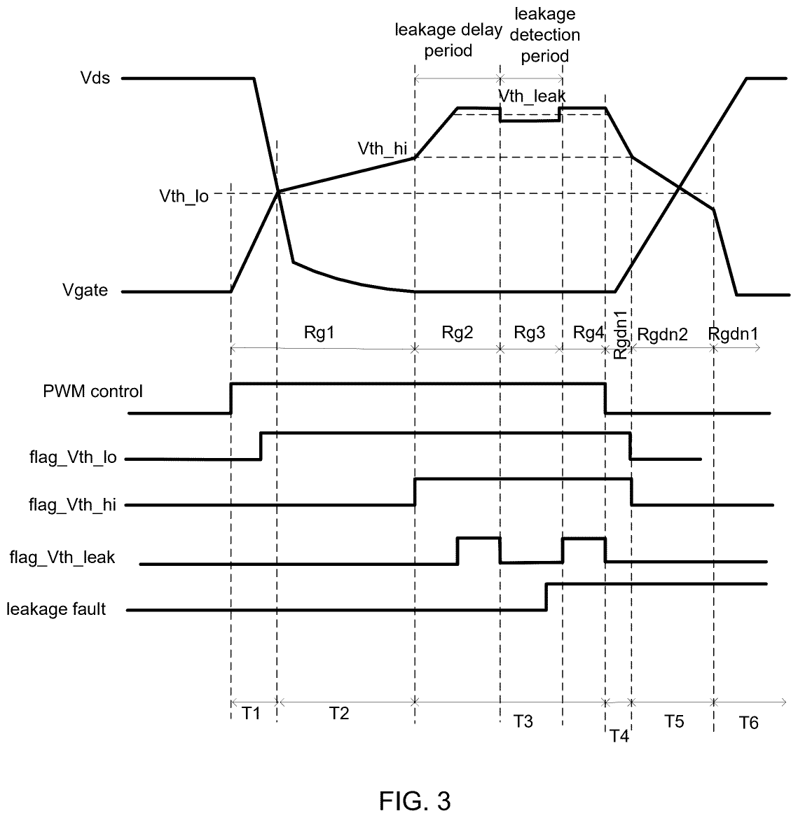

The period T1 (and the remaining periods T2 through T6) may be better appreciated through a consideration of the example timing diagram shown in FIG. 3. The PWM control signal is asserted to signal to the logic circuit 245 to control the gate drive circuit 215 to begin charging the gate voltage through the pull-up impedance Rg1 to begin period T1, during which the gate voltage (Vgate) rises rapidly. Period T1 continues until the gate voltage rises to the low threshold voltage Vth_lo, whereupon the comparator 230 asserts the flag_Vth_lo signal to signal the beginning of period T2. Since the threshold voltage is then satisfied for the power switch transistor, the Miller plateau period for the power switch transistor M1 begins during the period T2. However, the Miller plateau period for GaN devices is indistinct such that the gate voltage continues to rise during period T2 at a reduced rate as compared to the voltage rises during period T1. Period T2 ends when the gate voltage rises above the high threshold voltage Vth_hi, whereupon the comparator 225 asserts the flag_Vth_hi signal is asserted to begin period T3.

In response to the assertion of the flag_Vth_hi signal, the logic circuit 245 controls the gate drive circuit 215 to implement a lower gate drive pull-down resistance denoted herein as Rg2 (Rg1 being greater than Rg2) during the period T3. The period T3 begins at the assertion of the flag_Vth_hi signal until the end of the turn-on period for the power switch transistor M1. In some implementations, the gate resistance Rg2 is maintained until the end of the period T3. However, gate leakage in enhancement-mode GaN devices such as the power switch transistor M1 is a significant concern. To detect whether the power switch transistor M1 has excessive gate leakage currents, the logic circuit 245 begins timing a leakage delay period in response to the assertion of the flag_Vth_hi signal. The leakage delay period has an extent such that the gate voltage will be asserted to the power supply voltage before the leakage delay period has ended (the power switch transistor M1 being fully on).

The drain-to-source voltage Vds across the power switch transistor has a steep drop during period T1 and the beginning of period T2 to then begin to more slowly decline until it is grounded with the power switch transistor M1 being fully on. At the expiration of the leakage delay period, the logic circuit 245 begins timing a leakage detection period and controls the gate drive circuit 215 to increase the gate pull-up impedance from Rg2 to Rg3, where Rg3 is larger than Rg2. Should there be excessive gate leakage, the increased gate pull-up impedance in combination with the leakage current causes the gate voltage to drop below a gate leakage threshold voltage Vth_leak during the leakage detection period. Referring again to FIG. 2, a comparator 235 asserts a flag_Vth_leak signal in response to the gate voltage exceeding the gate leakage threshold voltage Vth_leak. Prior to the end of the leakage delay period (the gate pull-up impedance still equaling Rg2), the gate voltage rises above the gate leakage threshold voltage to cause the assertion of the flag_Vth_leak signal. But at the end of the leakage delay period, the gate pull-up impedance is increased to Rg3 during the leakage detection period, which in the combination with excessive gate leakage causes the gate voltage to fall below the gate leakage threshold voltage Vth_leak such that the flag_Vth_leak signal is de-asserted. As used herein, a binary signal is deemed to be asserted when the signal is logically true, regardless of whether the true state is expressed in an active high or an active low convention. Conversely, a binary signal is deemed herein to be de-asserted when the signal is logically false, regardless of whether the false state is expressed in an active high or an active low convention.

The logic circuit 245 detects the de-assertion of the flag_Vth_leak signal during the leakage detection period as a leakage fault 220. Should the leakage fault 220 be detected across consecutive cycles of the power switch transistor M1, subsequent cycles may be blocked by the logic circuit 245 to protect the power switch transistor M1 from damage caused by the excessive leakage currents. For example, the gate leakage threshold voltage Vth_leak may be set such that should the leakage be within the milliampere range, the leakage fault 220 is deemed to be detected. At the expiration of the leakage detection period, the logic circuit 245 controls the gate drive circuit 215 to lower the gate pull-up impedance to a value Rg4 that is less than Rg3. In some implementations, Rg4 and Rg2 are equal. Alternatively, Rg4 may be less than Rg2.

In response to the de-assertion of the PWM control signal to end the turn-on period and begin the turn-off period for the power switch transistor M1, the logic circuit 245 begins the turn-off period for the power switch transistor beginning with the period T4. During period T4, the gate driver circuit 215 discharges the gate voltage through a relatively low gate drive pull-down resistance denoted as Rgdn1. The gate voltage drops rapidly due to this relatively low pull-down resistance and thus drops below the high threshold voltage Vth_hi to cause the comparator 225 to de-assert the flag_Vth_hi signal. The logic circuit 245 responds to this de-assertion by commanding the gate drive circuit 215 to discharge the gate voltage through a gate drive pull-down resistance denoted as Rgdn2 that is greater than Rgdn1 to begin the period T5. In addition, the logic circuit 245 begins timing a pull-down delay in response to the de-assertion of the flag_Vth_hi signal. At the expiration of the pull-down delay to end period T5 and being period T6, the logic circuit 245 again commands the gate drive circuit 215 to discharge the gate voltage through the Rgdn1 pull-down resistance to quickly discharge the gate voltage until it is grounded to complete the turn-off period.

Those of some skill in this art will by now appreciate that many modifications, substitutions and variations can be made in and to the materials, apparatus, configurations and methods of use of the devices of the present disclosure without departing from the scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

We claim:

1. An integrated circuit for a switching power converter, comprising:
a gate drive circuit configured to charge a gate of a GaN power switch transistor through a variable pull-up resistance including a first pull-up resistance and a second pull-up resistance and to discharge the gate of the GaN power switch transistor through a variable pull-down resistance including a first pull-down resistance and a second pull-down resistance, wherein the first pull-up resistance is greater than the second pull-up resistance, and wherein the second pull-down resistance is greater than the first pull-down resistance; and
a gate drive control circuit configured to command the gate drive circuit to charge the gate through the first pull-up resistance during an initial first portion of an on-time period for the GaN power switch transistor and to charge the gate through the second pull-up resistance during a second portion of the on-time period, wherein the gate drive control circuit is further configured to command the gate drive circuit to discharge the gate through the first pull-down resistance during an initial first portion of an off-time period for the GaN power switch transistor and to discharge the gate through a second pull-down resistance during a second portion of the off-time period.

2. The integrated circuit of claim 1, further comprising:
a gate voltage monitor configured to monitor a gate voltage of the GaN power switch transistor, wherein the gate drive control circuit is further configured to time a main turn-on delay for the GaN power switch transistor responsive to a comparison of the gate voltage to a first threshold voltage by the gate voltage monitor.

3. The integrated circuit of claim 2, wherein the gate voltage monitor comprises:
a first comparator configured to compare the gate voltage to the first threshold voltage, and wherein the gate drive control circuit is further configured to begin the timing of the main turn-on delay is response to an assertion of a pulse width modulation signal and to stop the timing of the main turn-on delay in response to an assertion of an output signal from the first comparator.

4. The integrated circuit of claim 3, wherein the gate voltage monitor further comprises:
a second comparator configured to compare the gate voltage to a second threshold voltage that is greater than the first threshold voltage, wherein the gate drive control circuit is further configured to command the gate drive circuit to charge the gate through the second pull-up resistance in response to an assertion of an output signal from the second comparator.

5. The integrated circuit of claim 4, wherein the gate voltage monitor further comprises:
a third comparator configured to compare the gate voltage to a leakage threshold voltage that is greater than the second threshold voltage, wherein the gate drive control circuit is further configured to begin a timing of a leakage delay period in response to the assertion of the output signal from the second comparator and to command the gate drive circuit to charge the gate through a third pull-up resistance in response to an expiration of the leakage delay period and to detect a leakage fault in response to a de-assertion of an output signal from the third comparator while the gate drive circuit charges the gate through the third pull-up resistance.

6. The integrated circuit of claim 5, wherein the gate drive control circuit is further configured to begin a timing of a leakage detection period at a termination of the leakage delay period and to command the gate drive circuit to charge the gate through the second pull-up resistance following a termination of the leakage detection period.

7. The integrated circuit of claim 4, wherein the gate drive control circuit is further configured to command the gate drive circuit to discharge the gate voltage through a second pull-down resistance in response to a de-assertion of the output signal from the second comparator.

8. The integrated circuit of claim 7, wherein the gate drive control circuit is further configured to begin a timing of a pull-down delay period in response to the de-assertion of the output signal from the second comparator and to command the gate drive circuit to discharge the gate through the first pull-down resistance in response to a termination of the pull-down delay period.

9. The integrated circuit of claim 1, wherein the gate drive circuit includes a first plurality of transistors coupled between the gate of the GaN power switch transistor and a power supply node, and wherein the gate drive control circuit includes a logic circuit configured to command a first number of transistors in the first plurality of transistors to switch on during the initial first portion of the on-time period and to command a second number of transistors in the first plurality of transistors to switch on during the second portion of the on-time period, wherein the first number of transistors in the first plurality of transistors is less than the second number of transistors in the first plurality of transistors.

10. The integrated circuit of claim 9, wherein the gate drive circuit further includes a second plurality of transistors coupled between the gate of the GaN power switch transistor and ground, and wherein the logic circuit is further configured to command a first number of transistors in the second plurality of transistors to switch on during the initial first portion of the off-time period and to command a second number of transistors in the second plurality of transistors to switch on during the second portion of the off-time period, wherein the first number of transistors in the second plurality of transistors is more than the second number of transistors in the second plurality of transistors.

11. The integrated circuit of claim 10, wherein the first plurality of transistors comprises a plurality of PMOS transistors, and wherein the second plurality of transistors comprises a plurality of NMOS transistors.

12. The integrated circuit of claim 10, wherein each transistor in the first plurality of transistors couples to the power supply node through a corresponding resistor.

13. A method of driving a gate of a GaN power switch transistor in a switching power converter, comprising:
charging the gate through a first pull-up resistance during an initial portion of an on-time period for the GaN power switch transistor while a gate voltage of the GaN power switch transistor is less than a first threshold voltage;
charging the gate through a second pull-up resistance that is less than the first pull-up resistance during a second portion of the on-time period while the gate voltage is greater than the first threshold voltage;
discharging the gate through a first pull-down resistance during an initial portion of an off-time period for the GaN power switch transistor while the gate voltage is greater than a first threshold voltage; and
discharging the gate through a second pull-down resistance during a second portion of the off-time period in response to the gate voltage falling below the first threshold voltage, wherein the second pull-down resistance is greater than the first pull-down resistance.

14. The method of claim 13, further comprising:
beginning a timing of a pull-down delay period in response to the gate voltage falling below the first threshold voltage during the off-time period; and
switching from discharging the gate through the second pull-down resistance to discharging the gate through the first pull-down resistance in response to an expiration of the pull-down delay period.

15. The method of claim 13, further comprising:
beginning timing a main turn-on delay period in response to a start of the on-time period; and
stopping the timing of the main turn-on delay period in response to the gate voltage rising above a second threshold voltage that is less than the first threshold voltage.

16. The method of claim 14, further comprising:
beginning timing a leakage delay period in response to the gate voltage rising above the first threshold voltage during the on-time period;
switching from charging the gate through the second pull-up resistance to charging the gate through a third pull-up resistance to begin a leakage detection period in response to an expiration of the leakage delay period; and
detecting a leakage fault in response to the gate voltage falling below a third threshold voltage during the leakage detection period.

17. The method of claim 16, further comprising stopping a cycling of the GaN power switch transistor in response to a repeated detection of the leakage fault.

18. A switching power converter, comprising:
an inductor;
a GaN power switch transistor connected to the inductor; and
a integrated circuit configured to: charge a gate of the GaN power switch transistor through a first pull-up resistance during an initial first portion of an on-time period for the GaN power switch transistor, charge the gate through a second pull-up resistance during a second portion of the on-time period, discharge the gate through a first pull-down resistance during an initial first portion of an off-time period for the GaN power switch transistor, and discharge the gate through a second pull-down resistance during a second portion of the off-time period.

19. The switching power converter of claim 18, wherein the first pull-up resistance is greater than the second pull-up resistance, and wherein the second pull-down resistance is greater than the first pull-down resistance.

20. The switching power converter of claim 18, wherein the inductor is a primary winding of a transformer.
